(19) United States
(12) Patent Application Publication
(10) Pub. No.: US 2011/0042130 A1
(43) Pub. Date: Feb. 24, 2011

(54) Multilayered wiring substrate and manufacturing method thereof

(75) Inventors: Chang Hyun Lim, Seoul (KR); Tae Hoon Kim, Suwon (KR); Young Ki Lee, Hwaseong (KR); Tae Hyun Kim, Seoul (KR); Ki Ho Seo, Seoul (KR)

Correspondence Address: STAAS & HALSEY LLP, SUITE 700, 1201 NEW YORK AVENUE, N.W., WASHINGTON, DC, 20005, US

(73) Assignee: Samsung Electro-Mechanics Co., Ltd., Suwon (KR)

(21) Appl. No.: 12/654,529

(22) Filed: Dec. 22, 2009

(30) Foreign Application Priority Data
Aug. 24, 2009 (KR) 10-2009-0078402

(51) Int. Cl. H05K 1/11; H01K 3/10; H05K 3/36

(52) U.S. Cl. 174/262; 29/850; 29/830

(57) ABSTRACT

A multilayered wiring substrate and a manufacturing method thereof are disclosed. The multilayered wiring substrate includes: a stacked body including an insulating member and first and second metal cores stacked with the insulating member interposed therebetween, and having a through hole penetrating the first and second metal cores; first and second insulation layers formed on an external surface, excluding an inner wall of the through hole, of the first and second metal cores, respectively; first and second inner layer circuit patterns and first and second outer layer circuit patterns formed on the first and second insulation layers, respectively; first and second via electrodes electrically connecting the first and second inner layer circuit patterns and the first and second outer layer circuit patterns; a third insulation layer formed on the inner wall of the through hole; and a through electrode made of a conductive material filled in the through hole and electrically connecting the first and second outer layer circuit patterns.

### CROSS-REFERENCE TO RELATED APPLICATIONS

This application claims the priority of Korean Patent Application No. 10-2009-0078402 filed on Aug. 24, 2009, in the Korean Intellectual Property Office, the disclosure of which is incorporated herein by reference.

### BACKGROUND OF THE INVENTION

1. Field of the Invention

The present invention relates to a multilayered wiring substrate (i.e., multilayered circuit board) and a manufacturing method thereof and, more particularly, to a multilayered wiring substrate having high machining accuracy (i.e., processing accuracy or machining precision) and good heat releasing characteristics, and its manufacturing method.

2. Description of the Related Art

In general, a printed circuit board (PCB) is formed by wiring copper wires on one surface or both surfaces of a board made of various thermosetting synthetic resins, disposing an IC or electronic components on the board, fixing them, implementing electrical wires therebetween, and coating the same with an insulator.

One of the issues in forming an electronic circuit by using an IC or electronic components on the PCB is heat releasing from components generating excess heat.

Namely, when a determined voltage is applied to electronic components, current flows, which inevitably results in the generation of heat due to resistance loss . In this case, the heat generated from certain electronic components is so weak that it is naturally cooled without causing a problem in their operation. In the case of certain other electronic components, namely, heating components, that have limitations in their natural cooling, so much heat is generated that these components have a continuously rising temperature, and therefore, they malfunction and are damaged due to the continual increase in temperature. That is, such heating degrades the overall reliability of the electronic products.

Thus, various substrate structures for heat releasing (or heat sinking) or having the ability of cooling generated heat have been proposed.

Recently, a metal core PCB using a metal member having good heat transfer characteristics has been proposed. The metal core PCB includes a metal substrate made of aluminum, a polymer insulation layer formed on the metal substrate, and electrical wiring formed on the polymer insulation layer. Although the metal core PCB has good heat releasing characteristics when compared with the general PCB made of a plastic material, its fabrication cost is high due to the fact that it uses high-priced polymer having a relatively high level of thermal conductivity.

In addition, as the trend of electronic products is for a general reduction in size, becoming thinner, having increasingly higher densities, and being promoted to have the form of a package, raw materials are being changed and the layer configurations of circuits increasingly have a complicated structure in order to form a finer pattern on the PCB and enhance reliability and design density.

Namely, as circuit complexity increases and the demands for high-density and small circuits increase, a double-sided PCB or a multilayered PCB (MLB) has come into general use.

The MLB additionally includes a wiring-available layer in order to extend a wiring region. In detail, the MLB includes an inner layer and an outer layer. A thin core is used as a material of the inner layer, and a 4-layered (two inner layers and two outer layers are attached by pre-preg) MLB is used. The MLB may be configured to have six layers, eight layers, or 10 or more layers according to the complexity of the circuits contained therein.

Inner layer circuits and outer layer circuits such as a power circuit, a ground circuit, a signal circuit, and the like are formed on the inner and outer layers, and the inner layers and outer layers are connected by using a via hole.

The MLB is advantageous in that the wiring density can be markedly increased; however, the fabrication process is complicated. In particular, it is difficult to accurately adjust the via hole to connect the inner layer circuits and the outer layer circuits. Thus, the stacking process of the via hole degrades mass-productivity and causes a defective MLB.

### SUMMARY OF THE INVENTION

An aspect of the present invention provides a multilayered wiring substrate having good machining accuracy (i.e., processing accuracy or machining precision) and good heat releasing characteristics, and a manufacturing method thereof.

According to an aspect of the present invention, there is provided a multilayered wiring substrate including: a stacked body including an insulating member and first and second metal cores stacked with the insulating member interposed therebetween, and having a through hole penetrating the first and second metal cores; first and second insulation layers formed on an external surface, excluding an inner wall of the through hole, of the first and second metal cores, respectively; first and second inner layer circuit patterns and first and second outer layer circuit patterns formed on the first and second insulation layers, respectively; first and second via electrodes electrically connecting the first and second inner layer circuit patterns and the first and second outer layer circuit patterns; a third insulation layer formed on the inner wall of the through hole; and a through electrode made of a conductive material filled in the through hole and electrically connecting the first and second outer layer circuit patterns.

The first and second insulation layers may be anode oxide films formed by performing an anodizing process on the first and second metal cores.

The third insulation layer may be an anode oxide film or a plugging ink formed when the anodizing process is performed on the first and second metal cores.

According to another aspect of the present invention, there is provided a multilayered wiring substrate including: a stacked body including an insulating member and first and second metal cores stacked with the insulating member interposed therebetween, and having a through hole penetrating the first and second metal cores; first and second insulation layers formed on an external surface, excluding an inner wall of the through hole, of the first and second metal cores, respectively; first and second outer layer circuit patterns formed on the first and second insulation layers, respectively; a third insulation layer formed on the inner wall of the through hole; and a through electrode made of a conductive material charged in the through hole and electrically connecting the first and second outer layer circuit patterns.

The first and second insulation layers may be anode oxide films formed by performing an anodizing process on the first and second metal cores.

The third insulation layer may be an anode oxide film or a plugging ink formed when the anodizing process is performed on the first and second metal cores.

According to another aspect of the present invention, there is provided a method for manufacturing a multilayered wiring substrate, including: forming a via hole in first and second metal cores; forming first and second insulation layers on an external surface and an inner surface, excluding an inner wall of the via hole, of the first and second metal cores; forming first and second inner layer circuit patterns and first and second outer layer circuit patters at the first and second insulation layers, and forming first and second via electrodes electrically connecting the first and second inner layer circuit patterns and the first and second outer layer circuit patterns, respectively; stacking the first and second metal cores with an insulating member interposed between; forming a through hole such that it penetrates the first and second metal cores; forming a third insulation layer on the inner wall of the through hole; and forming a through electrode electrically connecting the first outer layer circuit pattern and the second outer layer circuit pattern.

The forming of the first and second insulation layers may be performed by anodizing the first and second metal cores.

The forming of the third insulation layer may be performed by anodizing the first and second metal cores.

The forming of the third insulation layer may include: filling a plugging ink in the through hole; and re-forming a through hole in the plugging ink.

According to another aspect of the present invention, there is provided a method for manufacturing a multilayered wiring substrate, including: stacking first and second metal cores with an insulating member interposed therebetween; forming a through hole such that it penetrates the first and second metal cores; forming first and second insulation layers on an external surface, excluding an inner wall of the through hole, of the first and second metal cores, and forming a third insulation layer on the inner wall of the through hole; and forming first and second outer layer circuit patterns on the first and second insulation layers and forming a through electrode electrically connecting the first and second outer layer circuit patterns.

The forming of the first and second insulation layers may be performed by anodizing the first and second metal cores.

The forming of the third insulation layer may be performed by anodizing the first and second metal cores.

The forming of the third insulation layer may include: filling a plugging ink in the through hole; and re-forming a through hole in the plugging ink.

### BRIEF DESCRIPTION OF THE DRAWINGS

The above and other aspects, features and other advantages of the present invention will be more clearly understood from the following detailed description taken in conjunction with the accompanying drawings, in which:

FIG. 1 is a sectional view of a multilayered wiring substrate according to one exemplary embodiment of the present invention;

FIG. 2 is a sectional view of a multilayered wiring substrate according to another exemplary embodiment of the present invention;

FIGS. 3a to 3g are sectional views showing sequential processes of a method for manufacturing a multilayered wiring substrate according to one exemplary embodiment of the present invention; and

FIGS. 4a to 4d are sectional views showing sequential processes of a method for manufacturing a multilayered wiring substrate according to another exemplary embodiment of the present invention.

### DETAILED DESCRIPTION OF THE PREFERRED EMBODIMENT

Exemplary embodiments of the present invention will now be described in detail with reference to the accompanying drawings. The invention may, however, be embodied in many different forms and should not be construed as being limited to the embodiments set forth herein. Rather, these embodiments are provided so that this disclosure will be thorough and complete, and will fully convey the scope of the invention to those skilled in the art. In the drawings, the shapes and dimensions may be exaggerated for clarity, and the same reference numerals will be used throughout to designate the same or like components.

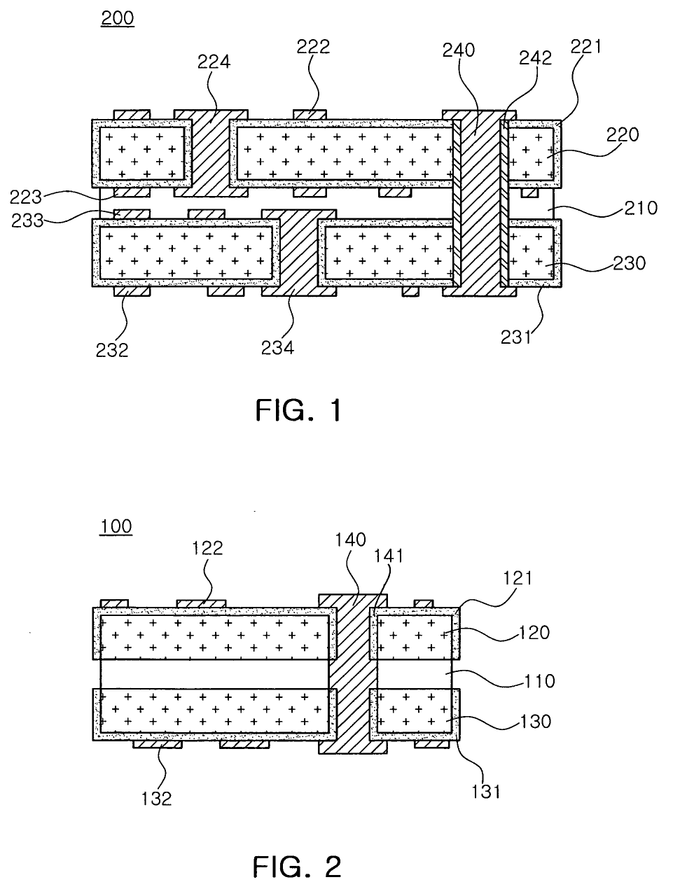

FIG. 1 is a sectional view of a multilayered wiring substrate according to an exemplary embodiment of the present invention.

With reference to FIG. 1, a multilayered wiring substrate 200 according to an exemplary embodiment of the present invention has a structure in which first and second metal cores 220 and 230 are stacked with an insulating member 210 interposed therebetween.

For the sake of explanation, the metal core stacked on the insulating member 210 will be known as a first metal core 220, and the metal core stacked below the insulating member 210 will be known as a second metal core 230.

Although not limited, the first and second metal cores 220 and 230 may be made of aluminum (Al), magnesium (Mg), titanium (Ti), zinc (Zn), tantalum (Ta), ferrite (Fe), nickel (Ni), and alloys thereof. The first and second metal cores 220 and 230 may be made of a metal that has good heat transfer characteristics and may be anodized.

A first insulation layer 221 is formed on the first metal core 220, and a first inner layer circuit pattern 223 and a first outer layer circuit pattern 222 are formed on the first insulation layer. The first insulation layer 221 is formed on an inner layer, of the first metal core substrate 220, in contact with the insulating member 210 as well as on an outer layer, of the first metal core substrate 220, not in contact with the insulating member 210.

The first outer layer circuit pattern 222 and the first inner layer circuit pattern 223 are electrically connected by a first via electrode 224.

A second insulation layer 231 is formed on the surface of the second metal core 230, and a second inner layer circuit pattern 233 and a second outer layer circuit pattern 232 are formed on the second insulation layer 231. The second insulation layer 231 is formed on an inner layer, of the second metal core substrate 230, in contact with the insulating member 210 as well as on an outer layer, of the second metal core substrate 230, not in contact with the insulating member 210.

The second outer layer circuit pattern 232 and the first inner layer circuit pattern 233 are electrically connected by a second via electrode 234.

Although not limited, the first and second insulation layers 221 and 231 may be anodized film formed by performing anodizing on the first and second metal cores 220 and 230. When the first and second metal cores 220 and 230 are made of aluminum, the first and second insulation layers 220 and 230 may be aluminum anodized insulation film Al₂O₃, which has a relatively high heat transfer characteristics of about 10 W/mK to 30 W/mK.

The anodized insulation film has good thermal conductivity when compared with a general insulator, and helps to make the wiring substrate thinner.

The first and second inner layer circuit patterns 223 and 233 and the first and second out layer circuit patterns 22 and 232 may be formed by using a plating process (electroless plating and electroplating), metal deposition, or an ink jet printing method. The first and second inner layer circuit patterns 223 and 233 and the first and second outer layer circuit patterns 22 and 232 may be formed to have initially designed patterns, or may be formed through a patterning process after the formation of a conductive film.

The first outer layer circuit pattern 222 form on the first metal core 220 and the second outer layer circuit pattern 232 formed on the second metal core 230 are electrically connected by a through electrode 240 that penetrates the first and second metal cores 220 and 230. The through electrode 240 forms a through hole penetrating the first and second metal cores 220 and 230, and may be formed through a via fill process after the formation of a third insulation layer 242. The through electrode 240 is electrically insulated with the first and second metal cores 220 and 230 by the third insulation layer 242. The third insulation layer 242 may be an anodized film formed by performing anodizing on the first and second metal cores 220 and 230. Or the third insulation layer 242 may be a plugging ink.

In the present exemplary embodiment, the multilayered wiring substrate has a four-storied structure, and if two or more metal cores are stacked, the multilayered wiring structure may have a four or more-storied structure.

The multilayered wiring substrate 200 according to the present exemplary embodiment has the structure in which two metal cores having good heat releasing characteristics are stacked. Thus, even when an element generating much heat is mounted thereupon, heat can be easily released, so the electronic components cannot malfunction nor cannot be damaged due to otherwise an increase in the temperature.

FIG. 2 is a sectional view of a multilayered wiring substrate according to another exemplary embodiment of the present invention. Different elements from those of the former exemplary embodiment will be described, and a detailed description of the same elements will be omitted.

With reference to FIG. 2, the multilayered wiring substrate 100 according to another exemplary embodiment of the present invention has a structure in which first and second metal cores 120 and 130 are stacked with an insulating member 110 interposed therebetween.

A first insulation layer 121 is formed on an outer surface, of the first metal core 120, not in contact with the insulating member 110, and a second insulation layer 131 is formed on an outer surface, of the second metal core 130, not in contact with the insulating member 110. Unlike the multilayered wiring substrate 200 according to the former exemplary embodiment of the present invention, the first insulation layer 121 is not formed on an inner layer, of the first metal core 120, in contact with the insulating member 110.

The first metal core 120 includes a first outer layer circuit pattern 122 formed on the first insulation layer, and the second metal core 130 includes a second outer layer circuit pattern 132 formed on the second insulation layer 131.

The first and second outer circuit patterns 122 and 132 are electrically connected by a through electrode 140 penetrating the first and second metal cores 120 and 130. The through electrode 140 forms a through hole penetrating the first and second metal cores 220 and 230, and may be formed through a via fill process performed to fill a conductive material in the through hole after the formation of a third insulation layer 141.

The through electrode 140 is electrically insulated from the first and second metal cores by the third insulation layer 141. The third insulation layer 141 may be an anodized film formed by performing anodizing on the first and second metal cores 120 and 130. The third insulation layer 141 may also be a plugging ink.

The multilayered wiring substrate 100 according to the present exemplary embodiment has the structure in which two metal cores having good heat releasing characteristics are stacked. Thus, even when an element generating excessive heat is mounted thereupon, heat can be easily released, so the electronic components can neither malfunction nor be damaged due to an increase in temperature. Thus, taking advantage of these characteristics, an element that generates excessive heat may be mounted on the first outer layer circuit pattern of the multilayered wiring substrate and an element vulnerable to heat may be mounted on the second outer layer circuit pattern.

In the present exemplary embodiment, the multilayered wiring substrate 100 has the dual metal core-stacked structure, but without being limited thereto, the multilayered wiring substrate 100 may have a structure in which two or more metal cores are stacked.

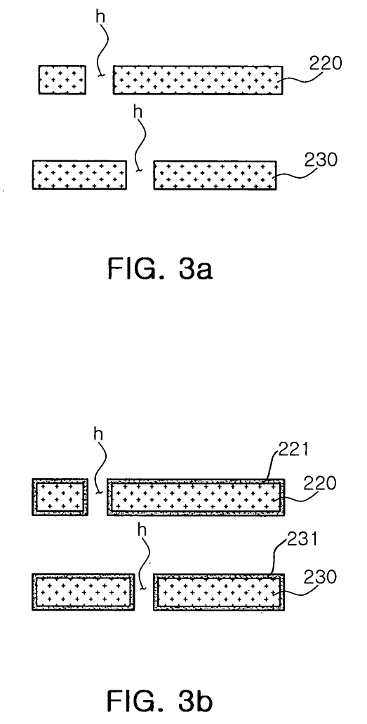

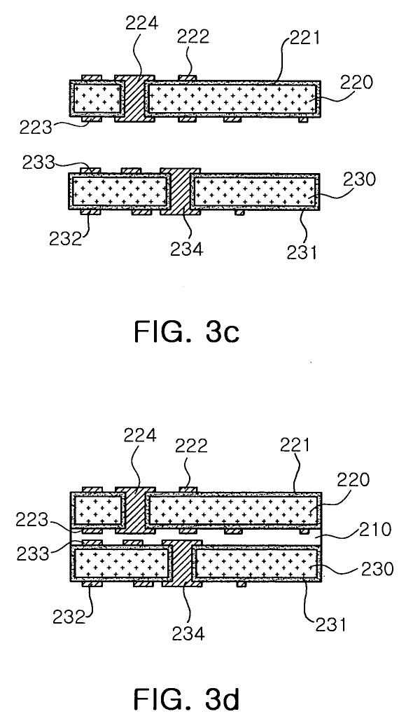

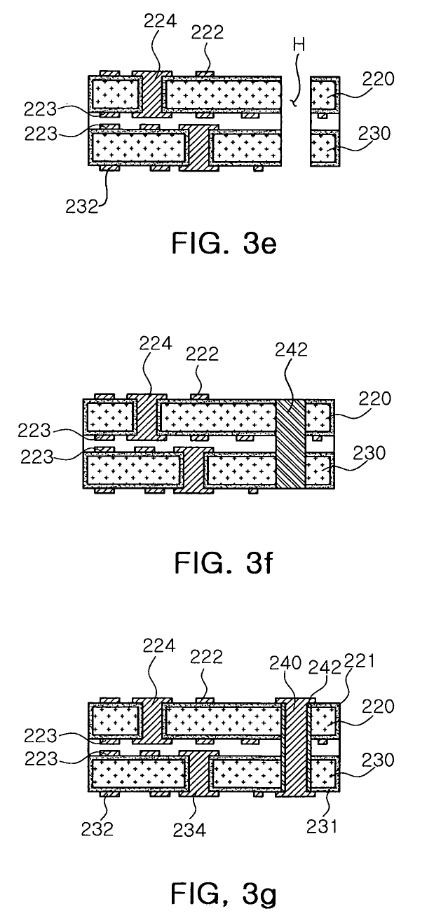

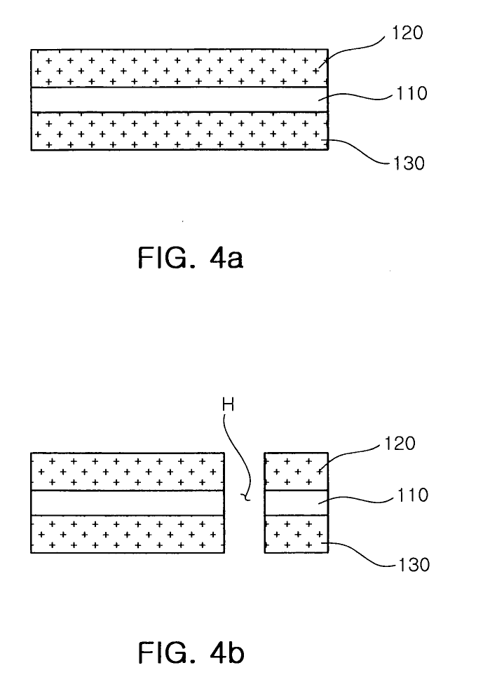

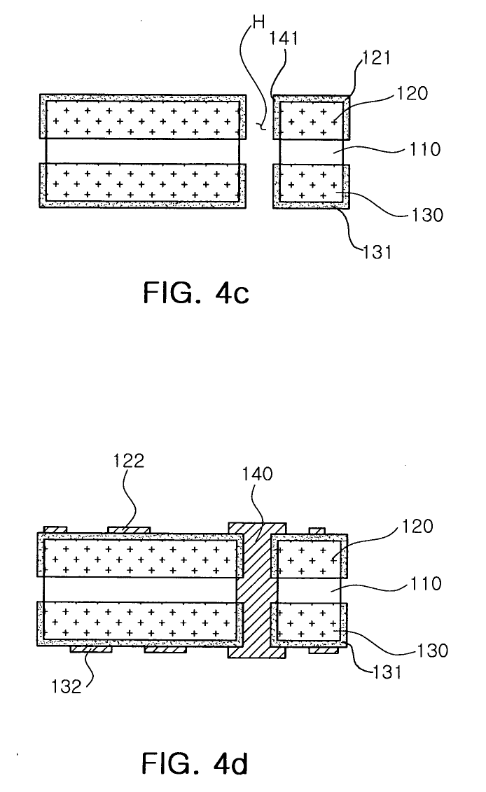

A method for manufacturing a multilayered wiring substrate according to an exemplary embodiment of the present invention will now be described with reference to FIGS. 3 and 4.

FIGS. 3a to 3g are sectional views showing sequential processes of a method for manufacturing a multilayered wiring substrate according to an exemplary embodiment of the present invention.

First, as shown in FIG. 3a, the through hole (h) for the formation of the via electrode is formed at the first and second metal cores 220 and 230, respectively.

Next, as shown in FIG. 3b, the first and second insulation layers 221 and 231 are formed on the first and second metal cores 220 and 230, respectively. The first and second insulation layers 221 and 231 may be formed by anodizing the first and metal cores 220 and 230.

And then, as shown in FIG. 3c, the first inner layer circuit pattern 223 and the first outer layer circuit pattern 222 are formed on the first insulation layer 221 formed on the first metal core 220.

The first inner layer circuit pattern 223 and the first outer layer circuit pattern 222 may be formed by using a plating process (electroless plating and electroplating), metal deposition, or an ink jet printing method. The first inner layer circuit pattern 223 and the first outer layer circuit pattern 222 may be formed to have initially designed patterns, or may be formed through a patterning process after the formation of a conductive film.

Thereafter, the via hole (h) is processed to form the first via electrode 224 in order to electrically connect the first inner layer circuit pattern 223 and the first outer layer circuit pattern 222. The processing method of the via hole (h) is not particularly limited, and the first via electrode 224 may be formed by plating or filling the via hole (h) with a conductive material.

The second inner layer circuit pattern 233 and the second outer layer circuit pattern 232 are formed on the second insulation layer 231 formed on the second metal core 230 in the same manner as described above. The via hole (h) is then processed to form the second via electrode 234 in order to electrically connect the second inner layer circuit pattern 233 and the second outer layer circuit pattern 232.

Thereafter, as shown in FIG. 3d, the first and second metal cores 220 and 230 are stacked with the insulating member 210 interposed therebetween. An insulating member in a semi-hardened state may be used as the insulating member 210, and for example, prepreg or the like may be used as the insulating member 210.

Subsequently, as shown in FIG. 3e, the through hole (H) penetrating the first and second metal cores 220 and 230 is formed. The through hole (H) may be formed through mechanical drilling such as that of a CNC (Computer Numerical Control) drill, or by using a laser. The laser may include a YAG laser or a CO₂ laser.

The method for manufacturing the multilayered wiring substrate according to the present exemplary embodiment features the formation of the through hole connecting the outer layer circuits of the first and second metal cores. Thus, compared with the method in which the through hole is formed on each of the first and second metal cores and the first and second metal cores are then stacked, time and cost otherwise taken and incurred in a through hole alignment process can be saved, and the possibility of misalignment generated when the through holes do not correspond precisely in stacking the first and second metal cores can be reduced.

Next, as shown in FIG. 3f, the through hole (H) is filled with plugging ink. And then, as shown in FIG. 3g, the plugging ink filling the through hole (H) is processed to form the third insulation layer 242. Thereafter, the through hole (H) is re-processed to form the through electrode 240 electrically connecting the first outer layer circuit pattern 222 formed on the first metal core 220 and the second outer layer circuit pattern 232 formed on the second metal core 230. The through electrode 240 is electrically insulated with the first and second metal cores 220 and 230 by the third insulation layer 242.

Although not shown, the third insulation layer may be formed by anodizing the first and second metal cores 220 and 230.

The method for manufacturing the multilayered wiring substrate with the four-storied structure has been described, but without being limited thereto, a multilayered wiring substrate having four or more layers can be manufactured.

FIGS. 4a to 4d are sectional views showing sequential processes of a method for manufacturing a multilayered wiring substrate according to another exemplary embodiment of the present invention.

First, as shown in FIG. 4a, the first and second metal cores 120 and 130 are stacked with the insulating member 110 interposed therebetween.

An insulating member in a semi-hardened state may be used as the insulating member 110, and for example, pre-preg may be used as the insulating member 110.

Next, as shown in FIG. 4b, the through hole (H) penetrating the first and second cores 120 and 130 is formed.

Then, as shown in FIG. 4c, the insulation layers 121, 131, and 141 are formed on each of the outer layers, of the first and second metal cores 120 and 130, which are not in contact with the insulating member 110, and on an inner wall of the through hole (H). The first and second insulation layers 121 and 131 formed on each of the outer layers of the first and second metal cores 120 and 130 may be formed by anodizing the first and second metal cores 120 and 130.

In this case, the anodizing process may be also performed on the inner wall of the through hole (H) to form the third insulation layer 141.

The present exemplary embodiment of the present invention has an advantage in that the insulation layers 121, 131, and 141 can be simultaneously formed on the first and second metal cores 120 and 130 and on the inner wall of the through hole (H).

Although not shown, after plugging ink is filled in the through hole (H), the through hole (H) may be re-processed by using a layer of plugging ink to form the third insulation layer 141.

Thereafter, as shown in FIG. 4d, the first and second outer layer circuit patterns 122 and 132 are formed on the first and second insulation layers 121 and 131 formed on each of the outer layers of the first and second metal cores 120 and 130.

Subsequently, the through hole (H) is processed to form the through electrode 140 electrically connecting the first and second outer layer circuit patterns. The processing method of the through hole (H) is not particularly limited, and the through hole (H) may be formed by plating or filling the through hole (H) with a conductive material.

The process of manufacturing the multilayered wiring substrate including two stacked metal cores has been described, but without being limited thereto, a multilayered wiring substrate having two or more metal cores can be manufactured in the same manner.

As set forth above, the multilayered wiring substrate according to exemplary embodiments of the invention has a structure in which two or more metal cores having good heat releasing characteristics are stacked. Thus, even when an element generating excessive heat is mounted thereupon, heat can be easily released, so the electronic components can neither malfunction nor damaged due to an increase in temperature.

In addition, the time and cost taken and incurred in an alignment process can be saved by the process of forming the through hole after stacking two or more metal cores, and the possibility of misalignment generated as the through holes do not correspond precisely in stacking the first and second metal cores can be reduced.

While the present invention has been shown and described in connection with the exemplary embodiments, it will be apparent to those skilled in the art that modifications and variations can be made without departing from the spirit and scope of the invention as defined by the appended claims.

What is claimed is:

1. A multilayered wiring substrate comprising:
a stacked body including an insulating member and first and second metal cores stacked with the insulating member interposed therebetween, and having a through hole penetrating the first and second metal cores;
first and second insulation layers formed on an external surface, excluding an inner wall of the through hole, of the first and second metal cores, respectively;
first and second inner layer circuit patterns and first and second outer layer circuit patterns formed on the first and second insulation layers, respectively;
first and second via electrodes electrically connecting the first and second inner layer circuit patterns and the first and second outer layer circuit patterns;
a third insulation layer formed on the inner wall of the through hole; and
a through electrode made of a conductive material filled in the through hole and electrically connecting the first and second outer layer circuit patterns.

2. The substrate of claim 1, wherein the first and second insulation layers are anode oxide films formed by performing an anodizing process on the first and second metal cores.

3. The substrate of claim 1, wherein the third insulation layer is an anode oxide film or a plugging ink formed when the anodizing process is performed on the first and second metal cores.

4. A multilayered wiring substrate comprising:
a stacked body including an insulating member and first and second metal cores stacked with the insulating member interposed therebetween, and having a through hole penetrating the first and second metal cores;
first and second insulation layers formed on an external surface, excluding an inner wall of the through hole, of the first and second metal cores, respectively;
first and second outer layer circuit patterns formed on the first and second insulation layers, respectively;
a third insulation layer formed on the inner wall of the through hole; and
a through electrode made of a conductive material charged in the through hole and electrically connecting the first and second outer layer circuit patterns.

5. The substrate of claim 4, wherein the first and second insulation layers are anode oxide films formed by performing an anodizing process on the first and second metal cores.

6. The substrate of claim 4, wherein the third insulation layer is an anode oxide film or a plugging ink formed when the anodizing process is performed on the first and second metal cores.

7. A method for manufacturing a multilayered wiring substrate, the method comprising:
forming a via hole in first and second metal cores;
forming first and second insulation layers on an external surface and an inner surface, excluding an inner wall of the via hole, of the first and second metal cores;
forming first and second inner layer circuit patterns and first and second outer layer circuit patters at the first and second insulation layers, and forming first and second via electrodes electrically connecting the first and second inner layer circuit patterns and the first and second outer layer circuit patterns, respectively;
stacking the first and second metal cores with an insulating member interposed between; forming a through hole such that it penetrates the first and second metal cores;
forming a third insulation layer on the inner wall of the through hole; and
forming a through electrode electrically connecting the first outer layer circuit pattern and the second outer layer circuit pattern.

8. The method of claim 7, wherein the forming of the first and second insulation layers is performed by anodizing the first and second metal cores.

9. The method of claim 7, wherein the forming of the third insulation layer is performed by anodizing the first and second metal cores.

10. The method of claim 7, wherein the forming of the third insulation layer may include: filling a plugging ink in the through hole; and re-forming a through hole in the plugging ink.

11. A method for manufacturing a multilayered wiring substrate, the method comprising:
stacking first and second metal cores with an insulating member interposed therebetween;
forming a through hole such that it penetrates the first and second metal cores;
forming first and second insulation layers on an external surface, excluding an inner wall of the through hole, of the first and second metal cores, and forming a third insulation layer on the inner wall of the through hole; and
forming first and second outer layer circuit patterns on the first and second insulation layers and forming a through electrode electrically connecting the first and second outer layer circuit patterns.

12. The method of claim 11, wherein the forming of the first and second insulation layers is performed by anodizing the first and second metal cores.

13. The method of claim 11, wherein the forming of the third insulation layer is performed by anodizing the first and second metal cores.

14. The method of claim 11, wherein the forming of the third insulation layer comprises:
filling a plugging ink in the through hole; and
re-forming a through hole in the plugging ink.
